(19) United States
(12) Patent Application Publication
(10) Pub. No.: US 2011/0132432 A1
(43) Pub. Date: Jun. 9, 2011

(54) SOLAR MODULE CONSTRUCTION

(75) Inventors: David Schultz, Berkeley, CA (US); Shondip Ghosh, Berkeley, CA (US); Christopher Grimmer, Oakland, CA (US); Kevin Fine, Redwood City, CA (US)

(73) Assignee: BANYAN ENERGY, INC., Berkeley, CA (US)

(21) Appl. No.: 12/954,533

(22) Filed: Nov. 24, 2010

Related U.S. Application Data
(60) Provisional application No. 61/283,097, filed on Nov. 25, 2009.

(51) Int. Cl. H01L 31/052; H01L 31/18

(52) U.S. Cl. 136/246; 438/65; 257/E31.127

(57) ABSTRACT

Various embodiments of a solar module design are disclosed. In some embodiments, a solar module comprises an optic having a sloped waveguide profile. The optic of the solar module is directly coupled to a receiver comprising a solar cell. The receiver is also coupled to a backplane of the module.

### CROSS REFERENCE TO OTHER APPLICATIONS

This application claims priority to U.S. Provisional Patent Application No. 61/283,097 entitled LAMINATED SOLAR MODULE CONSTRUCTION FOR FLAT PANEL CONCENTRATOR OPTIC filed Nov. 25, 2009, which is incorporated herein by reference for all purposes.

### BACKGROUND OF THE INVENTION

Existing solar module designs suffer various limitations. It would be useful to have improved solar module constructions.

### BRIEF DESCRIPTION OF THE DRAWINGS

Various embodiments of the invention are disclosed in the following detailed description and the accompanying drawings.

FIG. 1 illustrates an isometric view of an embodiment of a solar panel.

FIG. 2A illustrates a truncated cross sectional view of an embodiment of a module.

FIG. 2B illustrates a cross sectional view of an embodiment of a concentrator unit with a cutaway of the receiver stack.

FIG. 2C illustrates an embodiment of a manner in which the two main portions of a module are mated.

FIG. 2D illustrates a cross sectional view of an embodiment of a concentrator unit having a flat backplane.

FIG. 3 is a graph that contrasts an unfiltered solar spectrum with a filtered solar spectrum.

FIGS. 4A-4B illustrate isometric and side views of an embodiment of a manner to taper optics.

FIGS. 5A-5F illustrate different embodiments of backplane configurations.

FIGS. 6A-6B illustrate embodiments of frame linkages.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims, and the invention encompasses numerous alternatives, modifications, and equivalents. Numerous specific details are set forth in the following description in order to provide a thorough understanding of the invention. These details are provided for the purpose of example, and the invention may be practiced according to the claims without some or all of these specific details. For the purpose of clarity, technical material that is known in the technical fields related to the invention has not been described in detail so that the invention is not unnecessarily obscured.

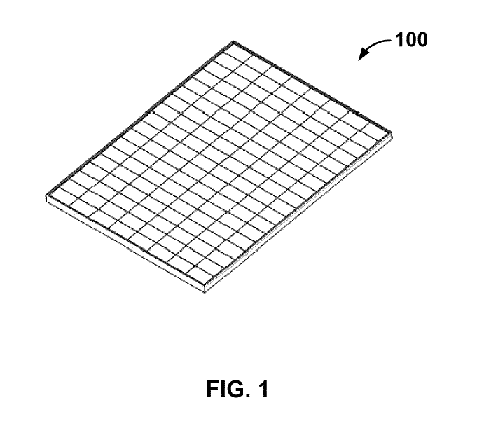

Solar energy modules are employed for applications such as concentrated photovoltaic (CPV) electricity generation and fluid heating. Various embodiments of a unique CPV solar module design are disclosed herein. FIG. 1 illustrates an isometric view of an embodiment of a solar panel 100. In some embodiments, module construction 100 integrates a flat, line-focus optic with a receiver in a panel form factor. An advantage of using line-focus optics is that standard single axis solar tracking may be employed instead of less standard two-axis tracking. In some embodiments, an optic of module 100 has a sloped or tapered waveguide profile and is directly coupled to a solar cell in module 100. The solar module designs disclosed herein provide the economic benefits of CPV while maintaining a low profile panel form factor. Maintaining a low profile panel form factor provides various advantages such as reduced transportation costs, reduced wind load, and compatibility with existing solar infrastructure such as commercially available tracking systems.

For illustrative purposes, some of the figures accompanying this description depict particular module designs. However, the disclosed techniques are not limited to these designs and may analogously be employed with respect to other designs. For example, one or more of the depicted and/or described layers of a module may be substituted with other layers and/or materials, one or more of the depicted and/or described layers of a module may be optional, one or more of the depicted and/or described layers of a module may be organized or ordered in a different manner, one or more other layers may be used in conjunction with and/or instead of some of the depicted and/or described layers of a module, etc.

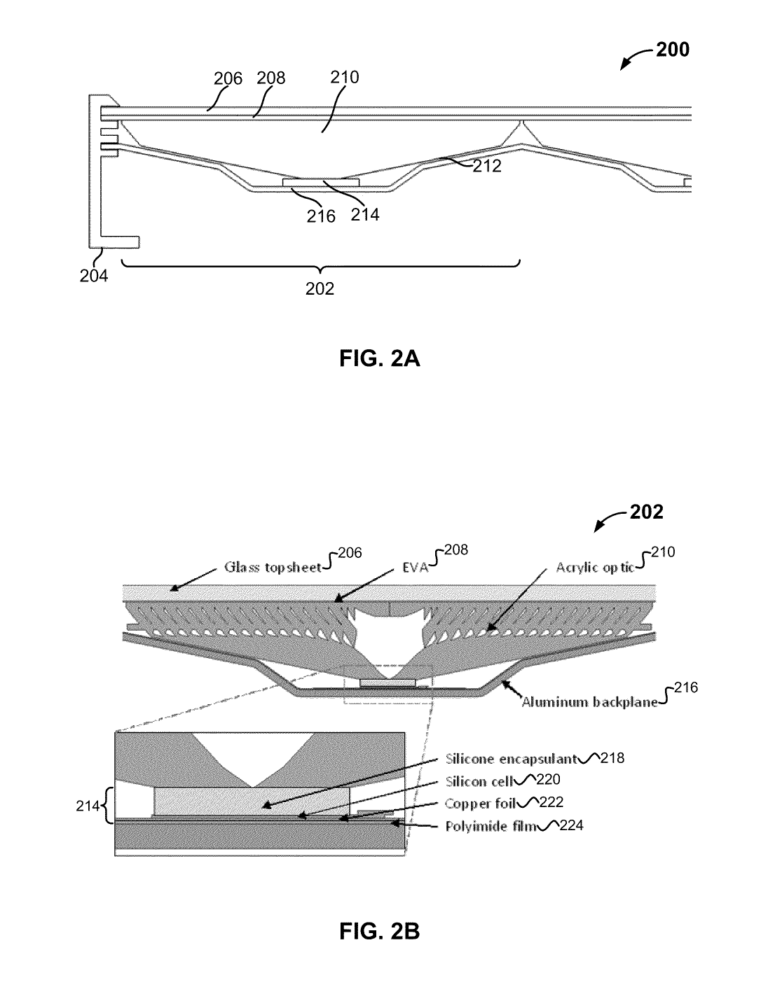

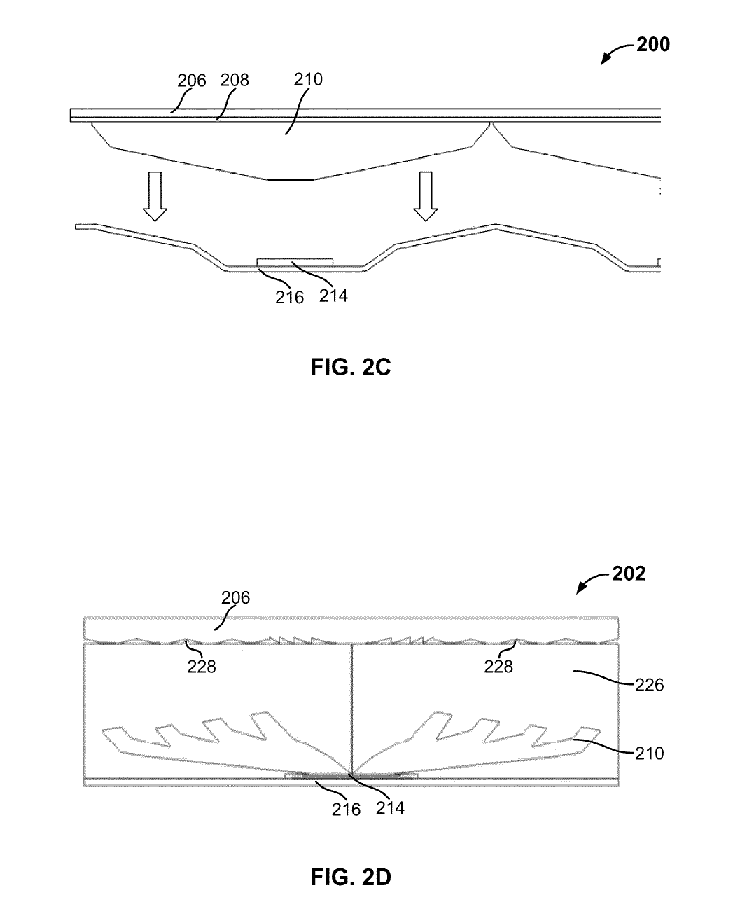

FIG. 2A illustrates a truncated cross sectional view of an embodiment of a module. In some embodiments, module 200 comprises panel 100 of FIG. 1. Module 200 comprises a plurality of concentrator units, such as concentrator unit 202, that are bound by a frame 204. As depicted in the given example, module 200 comprises a plurality of layers of materials including topsheet or primary optic 206, sublayer(s) 208, secondary optic 210, intermediate or cladding layer 212, receiver 214, and backplane 216. Each of these layers is further described in detail below.

Topsheet 206 facilitates transmission of incident light into module 200 and comprises a layer of transmissive material. In some embodiments, topsheet 206 comprises a primary optic of module 200. Low-iron float glass with low rates of photodegradation is one example of a material that may be used for topsheet 206. Topsheet 206 may serve any of a plurality of purposes. For example, topsheet 206 functions as a cover plate that serves as a barrier to protect module 200 from environmental and other external elements such as precipitation and ultraviolet radiation. Furthermore, topsheet 206 provides a substrate for the application of any desired antireflective and/or other coatings that filter the incident spectrum of energy. Moreover, topsheet 206 provides a flat datum surface on which to mount and/or align sublayer(s) 208 and/or optic 210 during assembly processes. In addition, topsheet 206 provides structural rigidity to module 200. In some embodiments, the material of topsheet 206 may be textured on either or both the top and bottom surfaces to influence the path of light. For example, rolled or patterned glass processes may be used to form lens features in a glass topsheet. In some cases, integrating optical elements within the topsheet material may simplify module construction, such as in the embodiment of FIG. 2D described further below.

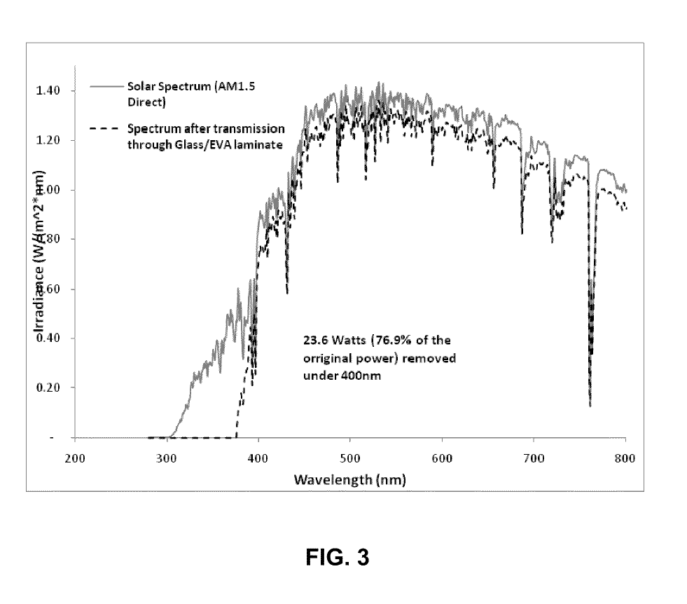

One or more optional sublayers 208 may be bound to the underside of topsheet 206. In some embodiments, sublayer(s) 208 comprise one or more polymers such as EVA (Ethylene Vinyl Acetate). Sublayer(s) 208 may serve any of a plurality of purposes. For example, sublayer(s) 208 may filter portions of the incident light spectrum that are potentially harmful to the underlying optic 210 or otherwise undesirable. For instance, ultraviolet light is known to degrade several classes of polymers, and adding a sublayer 208 to topsheet 206 that absorbs ultraviolet light can aid in preventing such degradation in each of the successive layers. FIG. 3 is a graph that contrasts an unfiltered AM1.5 standard solar test spectrum with a glass and EVA filtered spectrum. As depicted, the amount of energy within the ultraviolet range (i.e., ≦400 nm) is significantly reduced, if not eliminated, after transmission through low-iron glass and EVA layers comprising topsheet 206 and sublayer(s) 208, respectively. Furthermore, sublayer(s) 208 may facilitate bonding between topsheet 206 and optic 210. For example, if a brittle material such as glass is used for topsheet 206, a soft polymer sublayer 208 may be added as a conformal layer that promotes chemical adhesion between topsheet 206 and optic 210. Moreover, sublayer(s) 208 may enable bonding process options beyond traditional lamination processes such as solvent bonding or cold welding. Traditional elevated temperature lamination processes may deform, melt, or otherwise damage optic 210. High temperature lamination processes can be avoided by laminating a polymer substrate 208 onto topsheet 206 and subsequently using a low temperature process, such as solvent bonding or welding, to bond optic layer 210 to polymer substrate 208. Additionally, sublayer(s) 208 may manage thermal expansion and other related stresses at the topsheet 206 and optic 210 interface. For example, if a significant coefficient of thermal expansion mismatch exists between the topsheet 206 and optic 210 materials, a polymer sublayer 208 with an intermediate coefficient of thermal expansion may be inserted to alleviate thermal stresses that occur during heating or cooling of module 200.

Optic 210 comprises a transmissive material that guides incident light to a focal area coinciding with the receiver 214 interface. In some embodiments, optic 210 comprises a secondary optic of module 200. In some embodiments, optic 210 comprises a waveguide. In some embodiments, the optical components of module 200 form a concentrator optic. In some embodiments, the optical components of module 200 form an ATIR (Aggregated Total Internal Reflection) optic. In some embodiments, the optical components of module 200 comprise a concentrating layer that concentrates incident light and/or a waveguide layer that aggregates concentrated light and conveys it to a focal area. In some such cases, for example, integrated optical features in primary optic or topsheet 206 are responsible for concentrating light, and secondary optic or waveguide 210 is responsible for redirecting, aggregating, and/or conveying concentrated light to a focal area. In some embodiments, secondary optic 210 may further concentrate light received from primary optic 206. In some embodiments, the optic of module 200 comprises the type of concentrator optics disclosed in U.S. patent application Ser. Nos. 11/852,854 and 12/207,346, which are commonly owned by Banyan Energy, Inc. and incorporated herein by reference for all purposes. In some embodiments, the secondary optic or waveguide 210 has a sloped or tapered profile and may comprise an acrylic or other polymer material. Such a material may be employed for secondary optic 210 in conjunction with a primary optic 206 and/or sublayer(s) 208 that filter out harmful portions of the solar spectrum that would otherwise damage the material of secondary optic 210. In various embodiments, optic 210 may comprise a single part or multiple parts joined in an assembly.

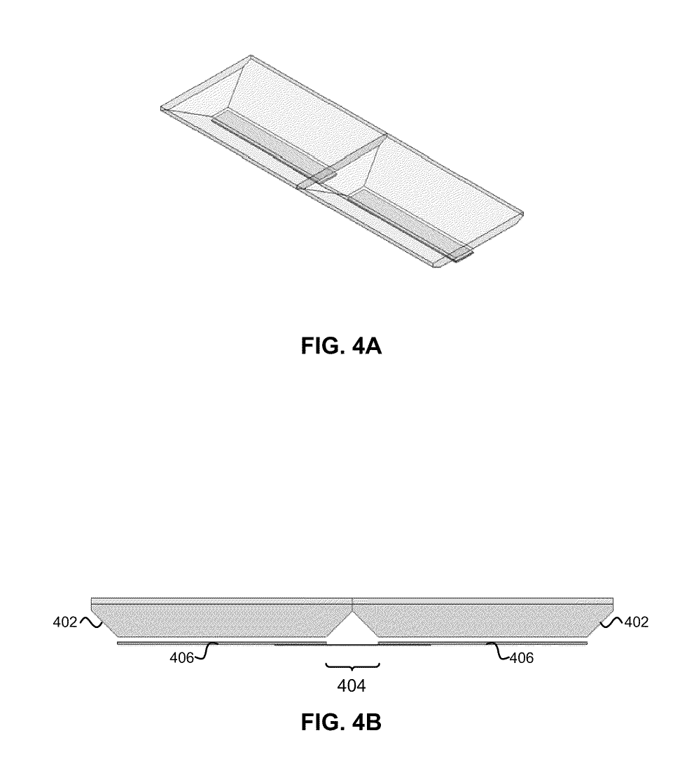

In some embodiments, it is desirable for adjacent cells of a module to be adequately spaced apart, for example, to avoid cell damage and provide an area for routing cell interconnections. In some embodiments, secondary optic 210 is sloped or tapered over inter-cell gaps so that light that would have otherwise been incident upon the inter-cell areas is instead redirected to the cell areas. FIG. 4A and FIG. 4B illustrate isometric and side views, respectively, of an embodiment of a manner to taper optics 402 over an inter-cell spacing 404 to redirect light onto cells 406. Such an optic profile minimizes inter-cell spacing losses that are typically inherent in traditional panel constructions and consequently results in improved module conversion efficiency.

An effective, panel-integrated linear concentrator optic is flat and consequently has a high aspect ratio (width dimension:height dimension). For example, in some embodiments, the aspect ratio is greater than 6:1. A high aspect ratio minimizes or at least reduces system costs associated with high nodality or a high number of concentrator units. For a silicon based cell technology, a mid-level geometric concentration ratio (aperture area:focal area) may also be desirable. For example, in some embodiments, the geometric concentration ratio is between 4:1 and 15:1. A more economical product may be feasible with an increased concentration ratio since the aperture area is covered by relatively lower cost optic materials compared to the focal area which affects the dimensions of higher cost receiver materials such as photovoltaic and/or heat exchange materials. Furthermore, solar concentrators allow for greater power output per unit of cell area, effectively making a more capital efficient use of solar cells. However, a high geometric concentration ratio poses a thermal risk that may result in undesirable electrical performance degradations. In some cases, significant thermal management costs may be incurred for geometric concentration ratios greater than approximately 15:1 in order to properly dissipate waste heat in CPV applications. For silicon-based photovoltaic products, a geometric concentration ratio ranging from 4:1 to 15:1 is most desirable considering the diminishing marginal economic benefit and the increasing thermal management challenge imposed at higher concentration levels.

An optional intermediate/cladding layer 212 may be placed between optic 210 and the receiver 214 and/or backplane 216 stacks. In some embodiments, intermediate/cladding layer 212 comprises a material that has a lower index of refraction than the material comprising optic 210. Silicone elastomers are one example of a low index optical cladding material that can encapsulate the cell, bond to optic 210, and tolerate conditions of high radiant flux. Intermediate/cladding layer 212 may serve any of a plurality of purposes. For example, intermediate/cladding layer 212 may facilitate the bonding of optic 210 to subsequent sublayers. Furthermore, intermediate/cladding layer 212 may function as a low optical index cladding that helps to further direct light to the focal area. Moreover, intermediate/cladding layer 212 may manage mismatched thermal expansion of materials and related stresses at the interfaces between optic 210 and the receiver 214 and/or backplane 216 stacks. In addition, intermediate/cladding layer 212 may encapsulate optic 210 and/or the receiver 214 stack and electrically isolate and protect them from the environment.

Receiver 214 interfaces with optic 210. In some embodiments, receiver 214 is directly coupled and/or in direct physical contact with optic 210. Receiver stack 214 includes a solar cell and may additionally include one or more other layers as further described below. The dimensions of receiver stack 214 are commensurate with the width of the focal area of optic 210. In some cases, it may be desirable to employ an optic 210 that facilitates focusing of light across a small focal area so that a receiver stack 214 that occupies a small footprint may be employed. Receiver stack 214 may serve any of a plurality of purposes. Most importantly, receiver stack 214 transforms concentrated light into a more useful form of energy. For example, in some embodiments, photovoltaic material placed at the focal area of optic 210 converts concentrated light energy into electricity. In other embodiments, concentrated light energy may be employed to heat a circulating fluid at the focal area of optic 210. Furthermore, receiver stack 214 transfers un-converted energy to one or more other layers of receiver stack 214 and/or backplane 216 to prevent thermal degradation.

FIG. 2B illustrates a cross sectional view of an embodiment of a concentrator unit 202 with a cutaway of receiver stack 214. FIG. 2B specifically provides one design example of the layers of materials that may be employed in module construction 200. As depicted, concentrator unit 202 includes glass topsheet 206, EVA sublayer 208, acrylic optic 210, receiver stack 214, and aluminum backplane 216. The cutaway of receiver stack 214 provides one design example of the layers of materials that may be employed for receiver stack 214. As depicted, receiver stack 214 comprises silicone encapsulant 218, silicon cell 220, copper foil 222, and polyimide film 224. In this embodiment, for example, a silicon-based photovoltaic cell 220 is soldered to a layer of conductive copper 222 which spreads heat and which in turn is bonded via a thermal grease to a thin (e.g., ˜200 μm) polyimide film 224 that insulates the electrical components from the metal backplane and that is bonded, potentially with another layer of thermal grease, to an aluminum backplane substrate 216 which further spreads heat and provides a structural substrate.

FIG. 2B illustrates one design embodiment of receiver stack 214. In other embodiments, receiver stack 214 may be constructed with any other appropriate combination of layers of materials that maintain electrical performance while achieving suitable thermal transfer. For example, in some embodiments, receiver stack 214 may comprise a layer of encapsulant, a solar cell, a copper heat spreader, and a layer of EVA. In another embodiment, receiver stack 214 may comprise a layer of encapsulant, a solar cell, and a layer of polymer composite. In yet another embodiment, receiver stack 214 may comprise a first layer of encapsulant, a layer of glass, a second layer of encapsulant, a solar cell, a third layer of encapsulant, an insulating film, and an aluminum heat spreader. In this embodiment, glass is employed as the primary structural material of backplane 216 and includes a thin layer of aluminum to provide heat spreading from the backside of the focal area. In any of the aforementioned as well as any other appropriate receiver stack 214 embodiments, any of a variety of bonding agents and/or solder compounds may be employed to join adjacent layers of receiver stack 214.

Backplane 216 interfaces with optic 210 and/or receiver stack 214. In various embodiments, backplane 216 may comprise a sheet of polymer, ceramic, metal, or any other appropriate material and/or a composite sheet of a plurality of such materials. Backplane 216 may serve any of a plurality of purposes. For example, backplane 216 functions as a rigid substrate upon which to mount and precisely locate receiver stack 214. Furthermore, backplane 216 may provide datum surfaces for co-location of the focal area of optic 210 with receiver 214. Moreover, backplane 216 provides structural rigidity to module 200 and serves as a barrier to environmental and other external elements. In addition, backplane 216 provides surface area for convective heat transfer.

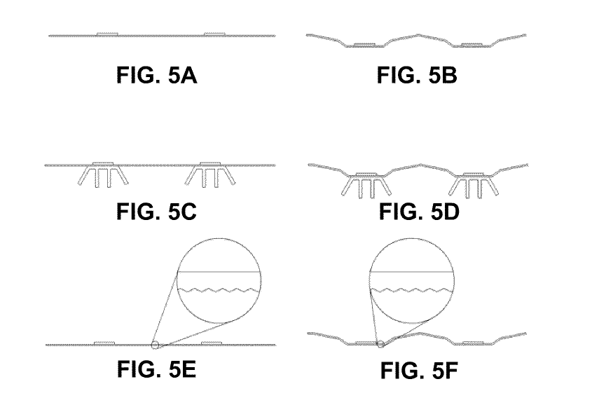

Not all of the light energy concentrated onto receiver 214 is converted into electricity or an otherwise useful form. Some of the energy may be transferred through receiver stack 214 to surrounding structures as heat. Localized heating occurs near the focal area of optic 210. This heat is dissipated primarily through convective heat loss from the backplane 216 structure. Receiver stack 214 plays an important role in transferring and spreading heat away from receiver 214. In order to decrease temperatures within module 200, localized or distributed heat sink structures may be used to increase backplane 216 surface area, thereby encouraging convective heat transfer. Examples of convective heat transfer structures that may be employed include heat sink fins and textured surfaces. In some cases, for instance, texturing a surface to a certain average angle may increase backplane surface area proportional to the inverse of the cosine of the aforementioned texture angle. Various heat sink options are further described below with respect to the description of FIG. 5.

In some embodiments, backplane 216 may be constructed to have a camber to more effectively force optic 210 into position against topsheet 206. For example, a composite backplane comprising glass, encapsulant material (e.g., EVA), and aluminum coated with an insulating film may be constructed to have a significant bend, or camber, in the direction of topsheet 206 after lamination. Such a bias in the shape of backplane 216 may be beneficial during assembly because a frontward force is provided by the backplane when it is forced flat against the array of optics. A cambered backplane 216 may be used to pin optic 210 to topsheet 206.

The embodiments of FIGS. 2A-2B depict a backplane 216 having a corrugated structure. Corrugations in backplane 216 may be produced, for example, via bending and/or roll-forming processes. In some embodiments, the corrugation profile of backplane 216 matches the profile of optic 210 and serves to constrain the focal area of optic 210 relative to receiver stack 214. That is, the sloped surfaces of corrugated backplane 216 serve as a seat that precisely fixes the location of a sloped or tapered optic 210 when mated. A backplane 216 having a corrugated structure inherently provides co-location or registration features for aligning the optic focal area over receiver 214 by constraining the horizontal motion and positioning of optic 210.

In some embodiments, assembly of the optical components of module 200 (e.g., topsheet 206, sublayer(s) 208, and/or optic 210) may be performed in parallel with the assembly of receiver stack 214 and backplane 216. Such a parallel assembly with a simplified mating step is a unique aspect of a module 200 design having a corrugated backplane 216. For example, a relatively low tech process may be employed to simply slide and/or fit the optical portion into the troughs of the corrugated backplane. FIG. 2C illustrates an embodiment of a manner in which the two main portions of module 200 may be mated with high precision due to the datum surfaces provided by corrugated backplane 216. In some such cases, the precision of the corrugated surfaces may at least in part dictate the precision of registering or co-locating the focal area of optic 210 relative to the cell area of receiver 214.

Floating position tolerances that account for misalignments in positioning receiver 214 with respect to backplane 216 as well as positioning optic 210 with respect to receiver 214 may at least in part determine the extent to which to oversize receiver 214 to ensure complete or nearly complete coverage of the focal area of optic 210 on the cell area of receiver 214. Because of co-location of optic 210 with features of backplane 216 in the corrugated construction, the precision with which the optic focal areas are located relative to the receivers 214 is limited primarily by the positional tolerances of the press or roll-forming processes used to produce the bends in backplane 216. The corrugated construction, therefore, reduces the need to oversize receiver 214 to account for registration tolerances associated with positioning optic 210 on top of receiver 214. In some such cases, the extent to which to oversize receiver 214 is primarily constrained by the precision of positioning receiver 214 on backplane 216.

Although the embodiments of FIGS. 2A-2C depict a corrugated backplane structure, in other embodiments, backplane 216 of module 200 may be flat or of a different shape. In addition to a bending or other shaping process to create the corrugation, a corrugated backplane may also require a special positioning tool for laminating receivers 214 in the troughs of the corrugated structure. Such shaping and/or positioning tooling costs, however, may be undesirable. In some embodiments, a flat backplane may instead be employed for module 200 at the expense, however, of better optic positioning equipment and/or a more oversized receiver 214 to account for registration tolerance in positioning optic 210 over receiver 214. In some embodiments, a flat backplane may be more desirable because it provides more design flexibility in the profile of optic 210 since optic 210 does not have to be matched to the profile of the backplane.

FIG. 2D illustrates a cross sectional view of an embodiment of a concentrator unit having a flat backplane. As depicted in the given example, concentrator unit 202 of FIG. 2D includes a primary optic or topsheet 206 having integrated optical features, secondary optic or waveguide 210, receiver stack 214, and flat backplane 216. In flat backplane embodiments, structural and positioning support for the optical components may at least in part be provided by a dedicated component such as rib 226. In the given example, rib 226 interfaces with the optical features of topsheet 206 via features 228 and with portions of waveguide 210, thereby facilitating horizontal registration of primary optic 206 and secondary optic 210 relative to one another. Rib 226 may further interface with receiver 214 and/or backplane 216. In addition to constraining the relative positions of primary optic 206 and secondary optic 210, rib 226 may also constrain the horizontal position and height of secondary optic 210 relative to receiver stack 214. Any appropriate material may be employed for rib 226. In some embodiments, the same material as secondary optic 210 is employed for rib 226.

FIGS. 5A-5F illustrate different embodiments of backplane configurations with attached receivers. FIG. 5A illustrates an embodiment of a flat backplane. Photovoltaic industry standard panels typically have large receivers that cover most of such a flat backplane and do not employ specific localized heat sink structures that further encourage convective cooling. Instead, traditional panels simply rely on a uniform distribution of energy and relatively uniform convection from the backplane surface. FIG. 5B illustrates an embodiment of a corrugated backplane. Such corrugated features conform to the shape of the optic, and the troughs of the corrugated backplane provide reduced landing areas for the receivers. Corrugations in the backplane may increase the bending stiffness of a panel beyond that achievable in a traditional flat backplane structure. In various embodiments, the convective surface area for heat transfer may be increased using finned and/or textured heat sinks FIG. 5C and FIG. 5E illustrate embodiments of using finned and textured methodologies, respectively, to increase convective heat transfer area on a flat backplane. Likewise, FIG. 5D and FIG. 5F illustrate embodiments of using finned and textured methodologies, respectively, to increase convective heat transfer area on a corrugated backplane. Although not depicted in FIGS. 5A-5F, in some embodiments, the convective heat transfer area may be further increased using both a finned and textured sink.

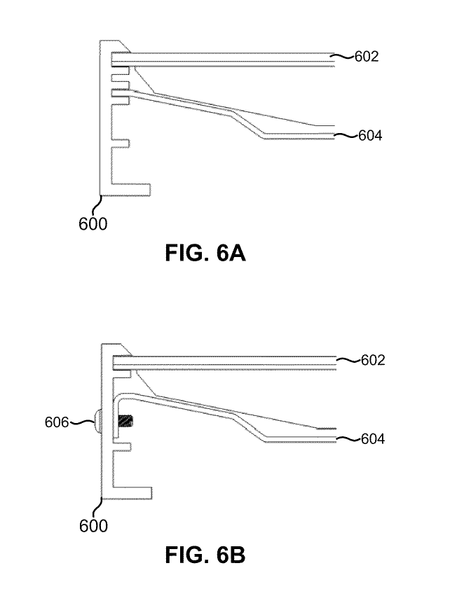

In addition to bonding between layers, an external frame, such as frame 204 of FIG. 2A, may be employed in some embodiments to mechanically link the layers. In various embodiments, any appropriate frame design may be employed, and frame 204 may be constructed using any one or more appropriate processes. For example, frame 204 may be machined, molded, extruded, etc. Moreover, frame 204 may be constructed from any appropriate material such as a metal like aluminum. In industry standard panels, typically only one layer interfaces with the frame. In some embodiments, at least two non-adjacent layers are anchored by frame 204 to achieve a stiffer structure. As depicted in FIG. 2A, in some cases, frame 204 interfaces with at least topsheet 206/sublayer(s) 208 and backplane 216. FIGS. 6A-6B illustrate embodiments of frame linkages shown in cross section in which at least two non-adjacent layers interface with the frame. In the embodiment of FIG. 6A, frame 600 is mechanically bound to the laminate structure via extensions that serve to grip the peripheries of topsheet 602 and backplane 604. In some embodiments, fasteners may be employed to attach one or more layers to the frame. In the embodiment of FIG. 6B, fastener 606 fastens backplane 604 to frame 600. The anchoring of both topsheet 602 and backplane 604 as well as the separation of topsheet 602 from backplane 604 by the secondary optic and other sub-layers results in an increased moment of inertia for the structure relative to traditional panels and therefore a more rigid panel structure.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A solar module, comprising:
an optic having a sloped waveguide profile;
a receiver directly coupled to the optic; and
a backplane coupled to the receiver.

2. A solar module as recited in claim 1, wherein the optic comprises a concentrator optic.

3. A solar module as recited in claim 1, wherein the optic comprises an ATIR (Aggregated Total Internal Reflection) optic.

4. A solar module as recited in claim 1, wherein the receiver is in direct physical contact with the optic.

5. A solar module as recited in claim 1, wherein the receiver comprises a solar cell.

6. A solar module as recited in claim 1, wherein the receiver comprises one or more layers of materials for thermal management.

7. A solar module as recited in claim 1, wherein the backplane comprises a corrugated structure.

8. A solar module as recited in claim 1, wherein the backplane comprises a textured surface.

9. A solar module as recited in claim 1, wherein the backplane comprises heat sink fins.

10. A solar module as recited in claim 1, further comprising a rib coupled to the optic that structurally supports and positions the optic.

11. A solar module as recited in claim 10, wherein the backplane is substantially flat.

12. A solar module as recited in claim 1, further comprising a topsheet through which light enters the solar module.

13. A solar module as recited in claim 12, wherein the topsheet comprises integrated optical features.

14. A solar module as recited in claim 1, further comprising a topsheet that provides concentrated light to the optic.

15. A solar module as recited in claim 1, further comprising a sublayer between the optic and a topsheet through which light enters the solar module.

16. A solar module as recited in claim 1, further comprising a cladding layer between the optic and the receiver.

17. A solar module as recited in claim 1, further comprising a frame for mechanically linking layers comprising the solar module.

18. A solar module as recited in claim 17, wherein the frame is coupled to at least two layers of the solar module.

19. A solar module as recited in claim 17, wherein the frame is coupled to the backplane and a topsheet through which light enters the solar module.

20. A method for constructing a solar module, comprising:
directly coupling an optic having a sloped waveguide profile to a receiver; and
coupling a backplane to the receiver.
